(19) United States
(12) Patent Application Publication
(10) Pub. No.: US 2001/0044192 A1
(43) Pub. Date: Nov. 22, 2001

(54) METHOD FOR MANUFACTURING STACKED CAPACITOR WITH STABLE CAPACITOR LOWER ELECTRODE

(76) Inventor: YOSHIHIRO TAKAISHI, TOKYO (JP)

Correspondence Address: SUGHRUE MION ZINN, MACPEAK & SEAS, 2100 PENNSYLVANIA AVENUE N W, WASHINGTON, DC, 20037

(21) Appl. No.: 09/303,614

(22) Filed: May 3, 1999

(30) Foreign Application Priority Data
May 1, 1998 (JP) 122322/1998

(51) Int. Cl. H01L 21/8242; H01L 21/20

(52) U.S. Cl. 438/396; 438/397; 438/399

(57) ABSTRACT

In a method for manufacturing a stacked capacitor, a first insulating layer is formed on a semiconductor substrate, and a first contact hole is perforated in the first insulating layer. Then, a conductive plug is buried in the first contact hole. Then, an etching stopper and a second insulating layer are formed on the first insulating layer and the conductive plug, and a second contact hole is perforated in the second insulating layer and the etching stopper. Then, an electrode layer is formed in the second contact hole. Then, the second insulating layer is etched by using the etching stopper. Finally, a capacitor dielectric layer and a capacitor upper electrode layer are formed on the electrode layer.

### BACKGROUND OF THE INVENTION

1. Field of the Invention

The present invention relates to a method for manufacturing a stacked capacitor used in a memory cell of a dynamic random access memory (DRAM) device.

2. Description of the Related Art

Generally in a DRAM device, a stacked capacitor is constructed by a capacitor lower electrode layer, a capacitor upper electrode layer and a capacitor dielectric layer therebetween.

In a first prior art method for manufacturing a stacked capacitor (see JP-A-6-29463 and JP-A-9-36320), a first insulating layer and an etching stopper are formed on a semiconductor substrate, and a contact hole is perforated in the etching stopper and the insulating layer. Then, a conductive layer is formed on the entire surface, and the conductive layer is patterned by using the etching stopper. Then, a cylindrical electrode is formed on the patterned conductive layer. Finally, a capacitor dielectric layer and a capacitor upper electrode layer are formed on the patterned conductive layer and the cylindrical electrode. This will be explained later in detail

In a second prior art method for manufacturing a stacked capacitor (see S. P. Sim et al., “A New Planar Stacked Technology (PST) for Scaled and Embedded DRAMs”, IEDM 96, pp. 597-600), a first insulating layer and an etching stopper are formed on a semiconductor substrate, and a contact hole is perforated in the etching stopper and the insulating layer. Then, a conductive plug is buried in the contact hole. Then, a cylindrical electrode is formed on the conductive plug. Finally, a capacitor dielectric layer and a capacitor upper electrode layer are formed on the cylindrical electrode. This also will be explained later in detail.

In the above-mentioned prior art methods, however, the capacitor lower electrode is located on the etching stopper made of silicon nitride, for example. Note that the contact characteristics of the capacitor lower electrode to silicon nitride are poor. As a result the capacitor lower electrode is easily peeled from the etching stopper. Particularly, if the capacitor lower electrode becomes higher, the capacitor lower electrode is much easily peeled from the etching stopper. Thus, the capacitor lower electrode is unstable.

### SUMMARY OF THE INVENTION

It is an object of the present invention to provide a method for manufacturing a stacked capacitor with a stable capacitor lower electrode.

According to the present invention, in a method for manufacturing a stacked capacitor, a first insulating layer is formed on a semiconductor substrate, and a first contact hole is perforated in the first insulating layer. Then, a conductive plug is buried in the first contact hole. Then, an etching stopper and a second insulating layer are formed on the first insulating layer and the conductive plug, and a second contact hole is perforated in the second insulating layer and the etching stopper. Then, an electrode layer is formed in the second contact hole. Then, the second insulating layer is etched by using the etching stopper. Finally, a capacitor dielectric layer and a capacitor upper electrode layer are formed on the electrode layer.

Thus, the electrode layer is not located on the etching stopper.

### BRIEF DESCRIPTION OF THE DRAWINGS

The present invention will be more clearly understood from the description set forth below, as compared with the prior art, with reference to the accompanying drawings, wherein:

FIGS. 1A through 1H are cross-sectional views for explaining a first prior art method for manufacturing a cylindrical stacked capacitor;

FIGS. 2A through 2E are cross-sectional views for explaining a second prior art method for manufacturing a cylindrical stacked capacitor;

FIGS. 3A through 3L are cross-sectional views for explaining a first embodiment of the method for manufacturing a stacked capacitor according to the present invention; and

FIGS. 4A through 4E are cross-sectional views for explaining a second embodiment of the method for manufacturing a stacked capacitor according to the present invention.

### DESCRIPTION OF THE PREFERRED EMBODIMENT

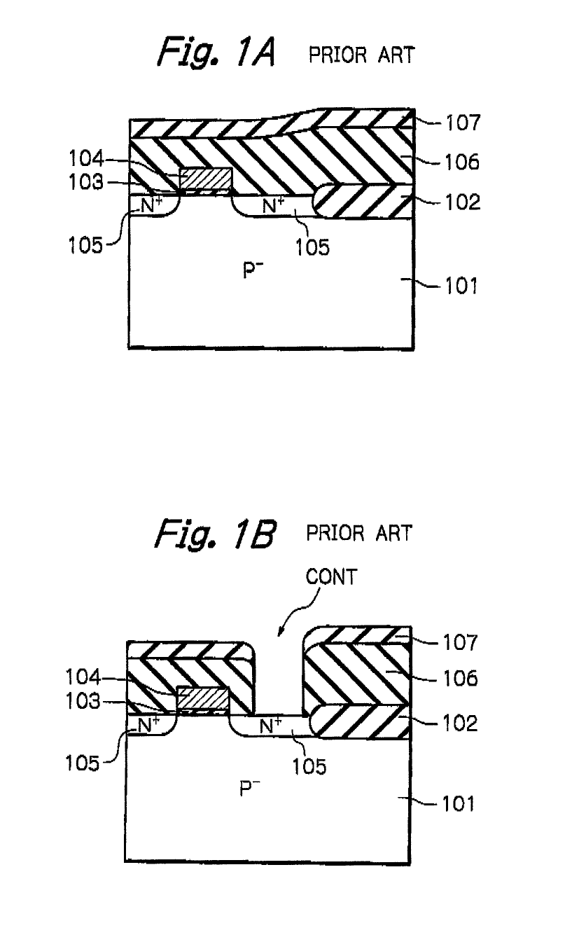

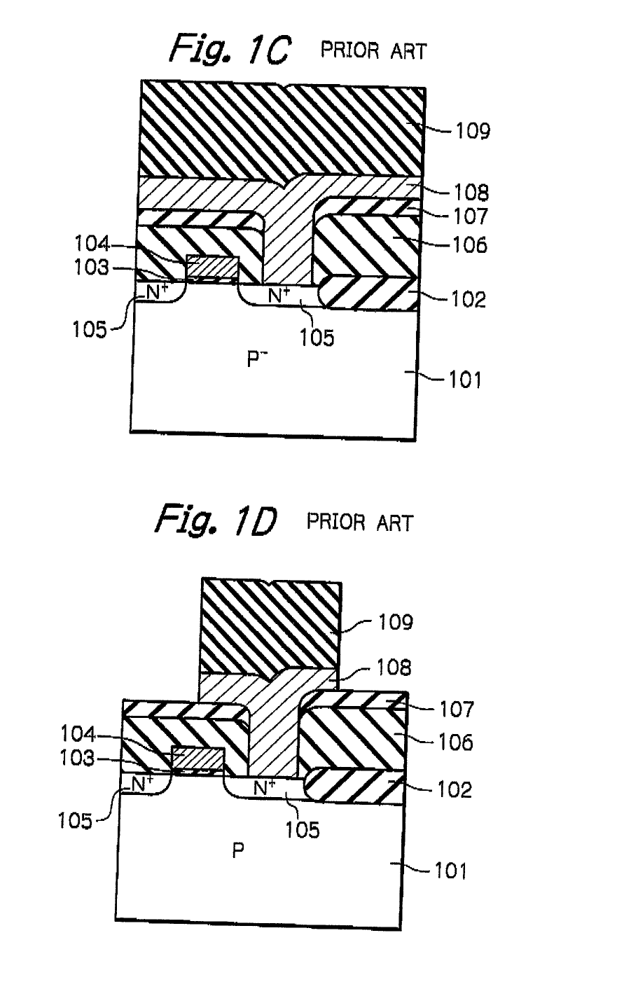

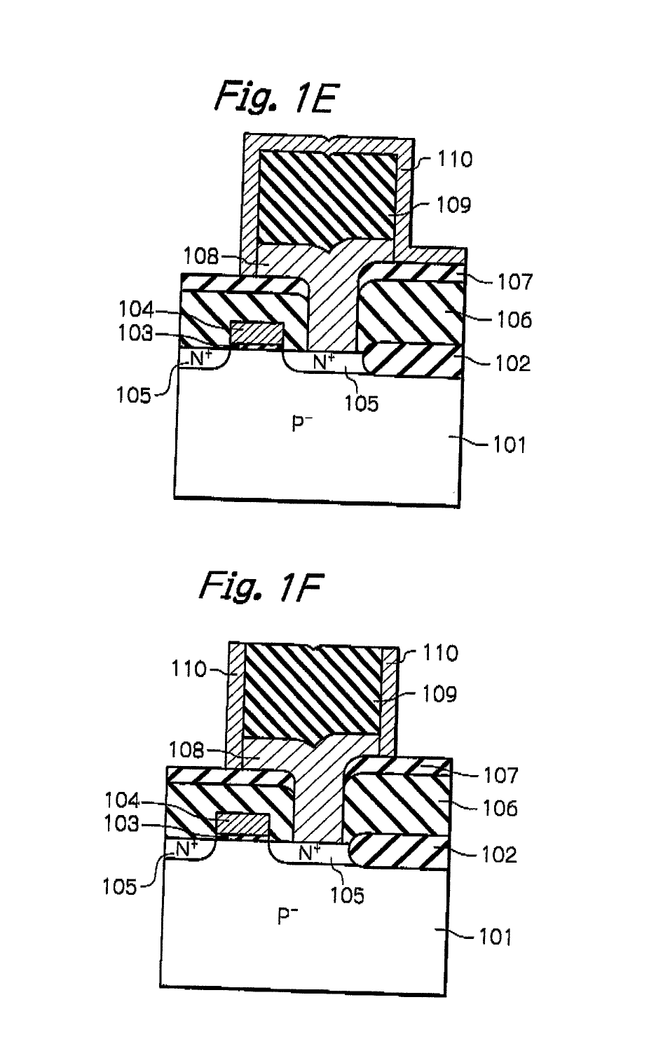

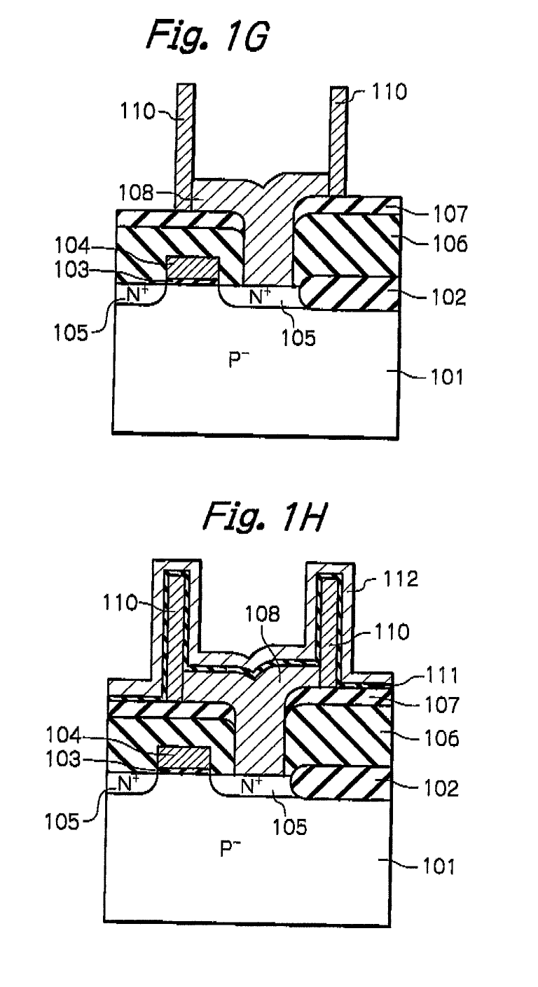

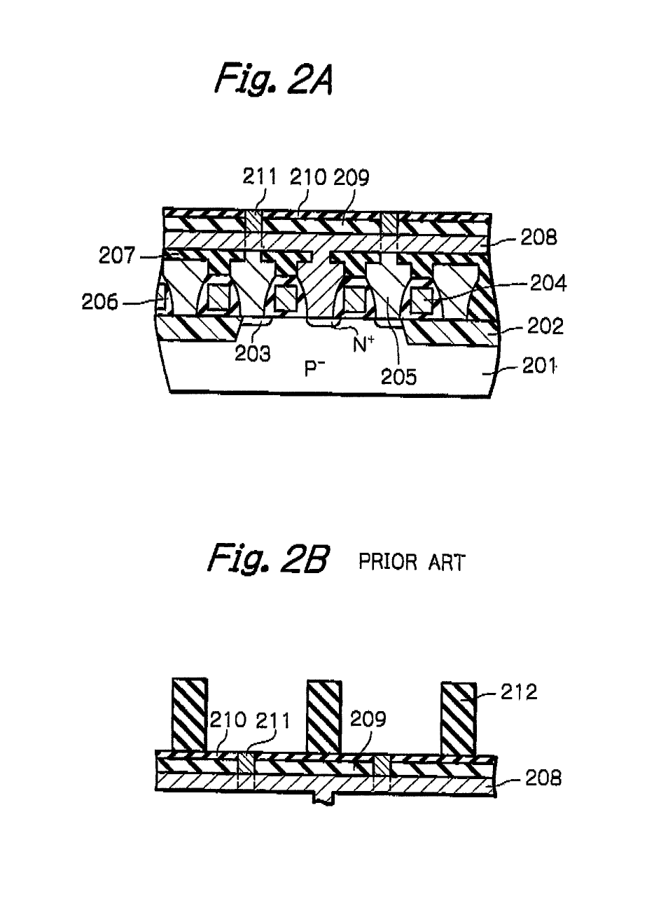

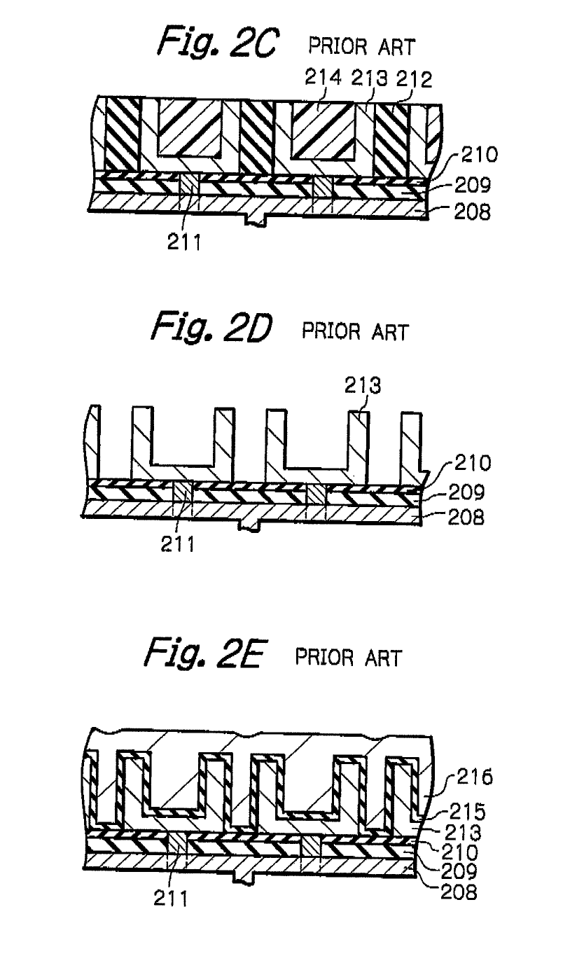

Before the description of the preferred embodiment, prior art methods for manufacturing a cylindrical stacked capacitor will be explained with reference to FIGS. 1A through 1H and FIGS. 2A through 2E.

FIGS. 1A through 1H are cross-sectional views for explaining a first prior art method for manufacturing a cylindrical stacked capacitor (see JP-A-6-29463 and JP-A-9-36320).

First, referring to FIG. 1A, a P-type monocrystalline silicon substrate 101 is thermally oxidized by using a local oxidation of silicon (LOCOS) process to grow a field silicon oxide layer 102 thereon. Then, the silicon substrate 101 is thermally oxidized to grow a gate silicon oxide layer 103. Then, a polycrystalline silicon layer is deposited by a chemical a vapor deposition (CVD) process and is patterned by a photolithography and etching process to form a word line or a gate electrode 104. Then, the gate silicon oxide layer 103 is anisotropically etched to expose source/drain areas of the silicon substrate 101. Then, N⁺-type impurity diffusion regions 105 are formed within the silicon substrate 101 in self-alignment with the gate electrode 104 by using an ion-implantation process. Then, an insulating layer 106 made of boron-including phosphosilicated glass (BPSG) is formed on the entire surface by a CVD process. Then, an etching stopper 107 made of silicon nitride is deposited on the entire surface by a CVD process.

Next, referring to FIG. 1B, a contact hole CONT is perforated in the etching stopper 107 and the insulating layer 106 by a photolithography and etching process.

Next, referring to FIG. 1C, a phosphorus-doped polycrystalline silicon layer 108 is deposited on the entire surface by a CVD process, and also, a silicon oxide layer 109 is deposited on the polycrystalline silicon layer 108 by a CVD process.

Next, referring to FIG. 1D, the silicon oxide layer 109 and the polycrystalline silicon layer 108 are patterned by a photolithography and etching process. As a result, the silicon oxide layer 109 and the polycrystalline silicon layer 108 become cylindrical.

Next, referring to FIG. 1E, a phosphorus-doped polycrystal line silicon layer 110 is deposited on the entire surface by a CVD process.

Next, referring to FIG. IF, the polycrystalline silicon layer 110 is etched by an anisotropic dry etching process. As a result, the polycrystalline silicon layer 110 is left as a sidewall layer, i.e., a cylindrical electrode. The sidewall polycrystalline silicon layer (cylindrical electrode) 110 as well as the polycrystalline silicon layer 108 serve as a capacitor lower electrode.

Next, referring to FIG. 1G, the silicon oxide layer 109 is etched by a wet etching process. In this case, since the etching stopper 107 is present, the insulating layer 106 is not etched.

Finally, referring to FIG. 1H, a capacitor dielectric layer 111 and a capacitor upper electrode layer 112 are formed on the entire surface, to complete a stacked capacitor.

In the stacked capacitor manufactured by the method as illustrated in FIGS. 1A through 1H, however, the capacitor lower electrode (108, 110) is located on the etching stopper 107 made of silicon nitride. Note that the contact characteristics of the capacitor lower electrode (108, 110) to silicon nitride is poor. As a result the capacitor lower electrode (108, 110) is easily peeled from the etching stopper 107. Particularly, if the capacitor lower electrode (108, 110) becomes higher, the capacitor lower electrode (108, 110) is much easier peeled from the etching stopper 107.

FIGS. 2A through 2E are cross-sectional views for explaining a second prior art method for manufacturing a cylindrical stacked capacitor (see S. P. Sim et al., “A New Planar Stacked Technology (PST) for Scaled and Embedded DRAMs” IEDM 96, pp. 597-600). Note that this stacked capacitor is adopted in a capacitor over bit line (COB) structured DRAM device.

First, referring to FIG. 2A, reference numeral 201 designates a P⁻type monocrystalline silicon substrate in which a field silicon oxide layer 202 and N⁺-type impurity diffusion regions 203 are formed. Also, reference numeral 204 designates a gate electrode, and 205 designates a polycrystalline silicon plug. The gate electrode 204 and the polycrystalline silicon plug 205 are electrically isolated from each other by insulating layers 206 and 207. Further, a bit line 208 is formed on the insulating layer 207 and crosses over the gate electrode 204.

In order to form a cylindrical stacked capacitor, an insulating layer 209 made of silicon oxide or the like is formed on the bit line 208, and an etching stopper 210 made of silicon nitride is formed on the insulating layer 209. Also, a contact hole is perforated in the etching stopper 210 and the insulating layer 209 by a photolithography and etching process. Then, a polycrystalline silicon plug 211 is buried in the contact hole.

Next, referring to FIG. 2B, a silicon oxide layer 212 is deposited on the entire surface by a CVD process, and is patterned by a photolithography and etching process. Thus, the silicon oxide layer 212 becomes a cylindrical spacer.

Next, referring to FIG. 2C, a polycrystalline silicon layer 213 is deposited on the entire surface by a CVD process, and a silicon oxide layer 214 is deposited on the polycrystalline silicon layer 213 by a CVD process. Then, the silicon oxide layer 214 and the polycrystalline silicon layer 213 are etched back by an anistropic dry etching process. Thus, the polycrystalline silicon layer 213 becomes a cylindrical electrode. Note that the polycrystalline silicon layer 213(cylindrical electorde) as well as the polycrystalline silicon layer 211 serve as a capacitor lower electrode.

Next, referring to FIG. 2D, the silicon oxide layers 212 and 214 are etched by a wet etching process. In this case, since the etching stopper 210 made of silicon nitride, the insulating layer 209 is not etched.

Finally, referring to FIG. 2E, a capacitor dielectric layer 215 and a capacitor upper electrode layer 216 are formed on the entire surface, to complete a stacked capacitor.

Even in the stacked capacitor manufactured by the method as illustrated in FIGS. 2A through 2E, the capacitor lower electrode (211, 213) is located on the etching stopper 210 made of silicon nitride. As a result the capacitor lower electrode (211, 213) is easily peeled from the etching stopper 210. Particularly, if the capacitor lower electrode (211, 213) becomes higher, the capacitor lower electrode (211, 213) is much easier peeled from the etching stopper 210.

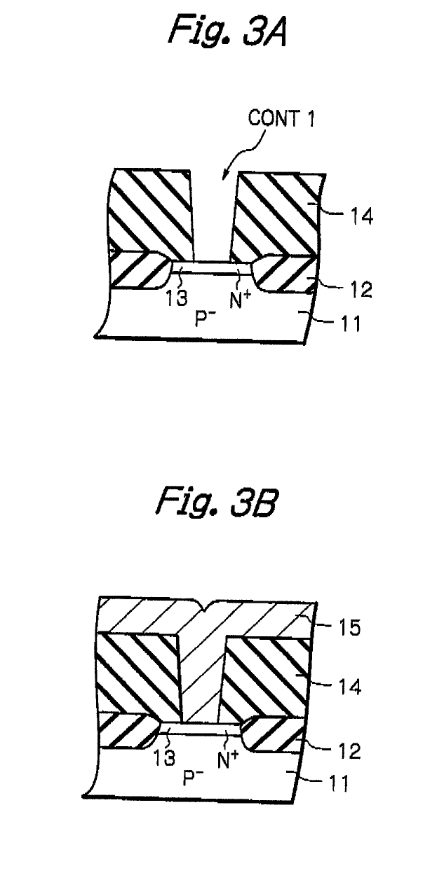

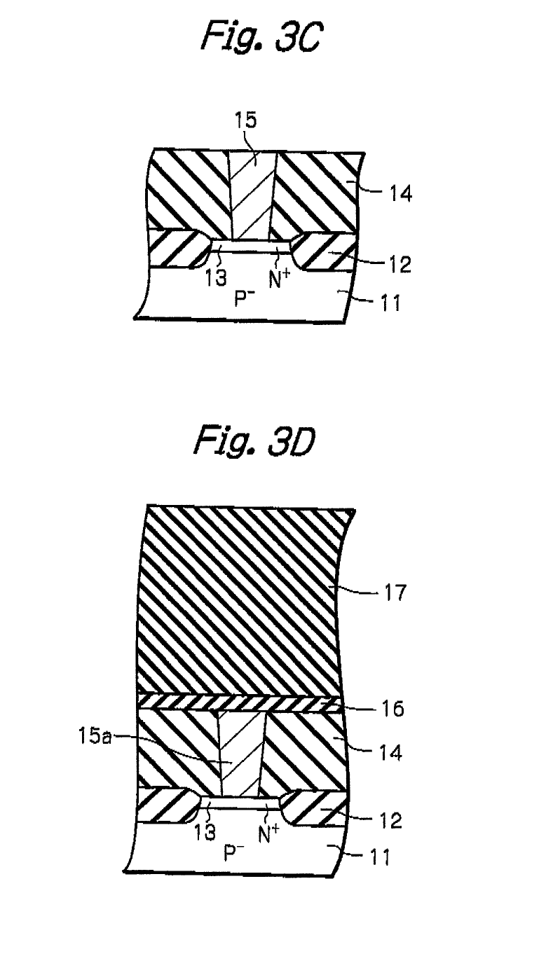

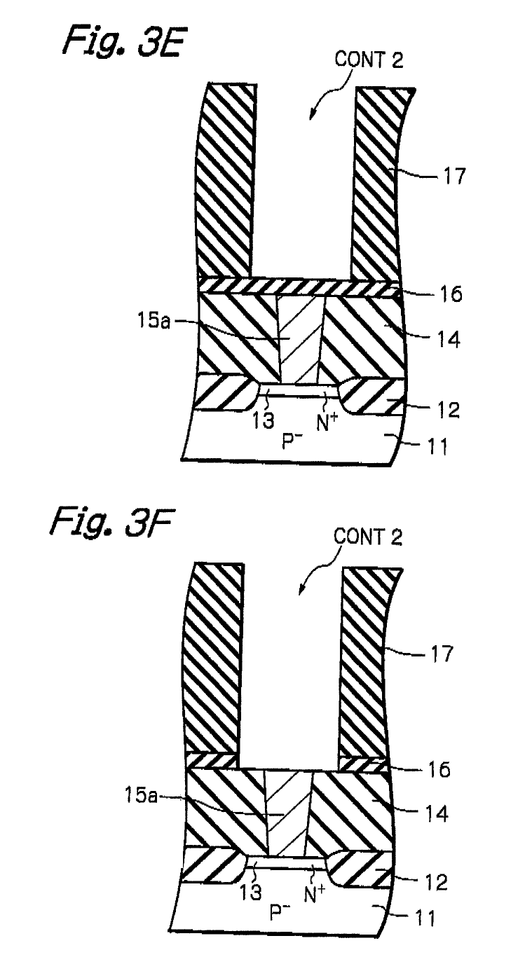

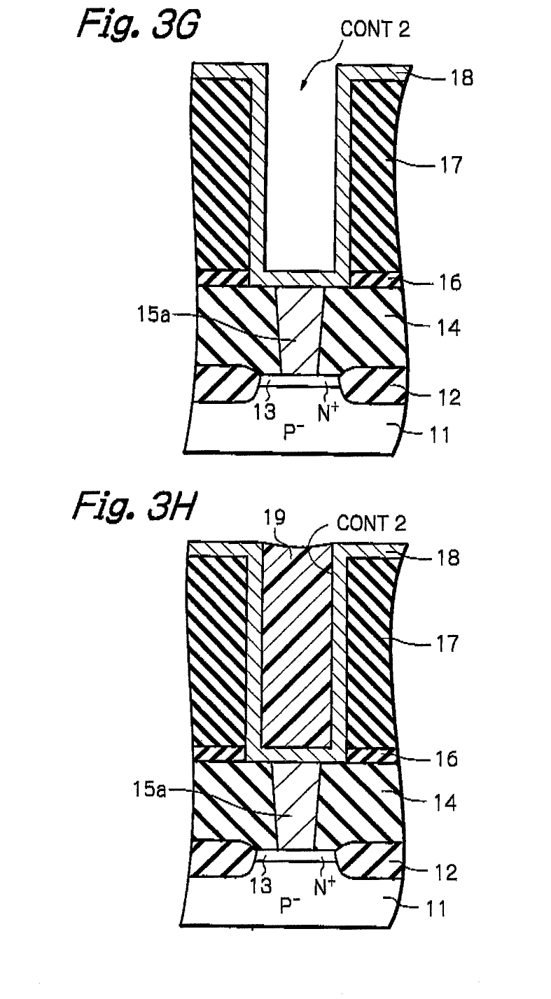

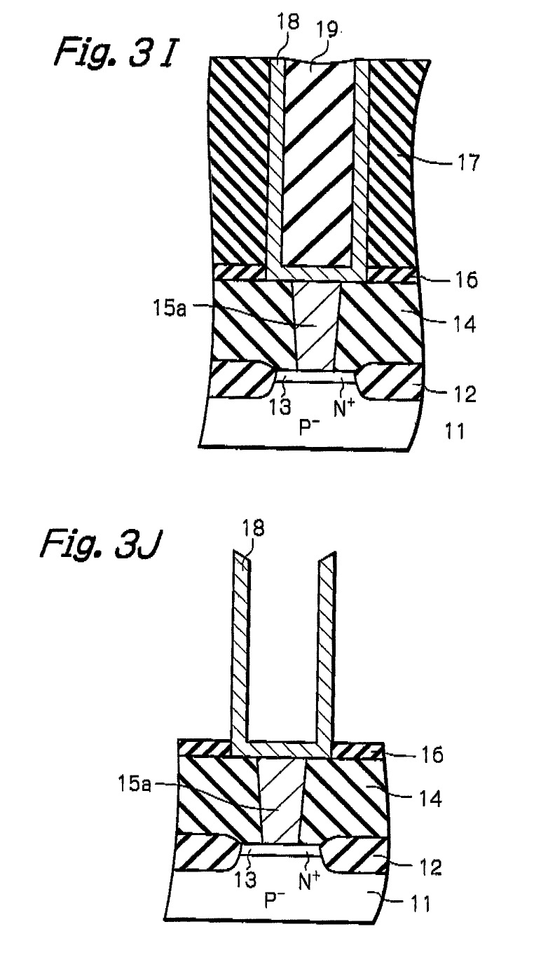

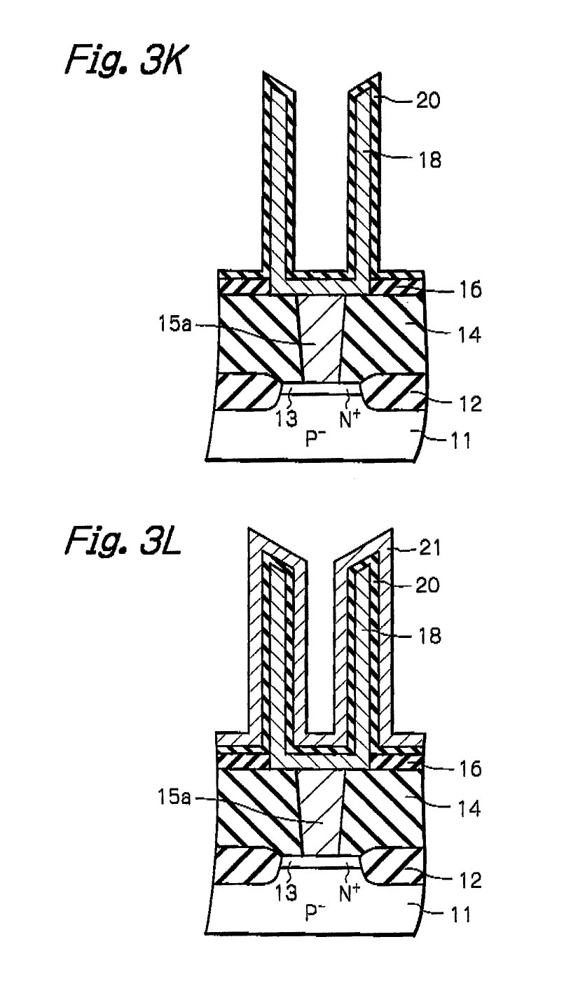

FIGS. 3A through 3L are cross-sectional views for explaining a first embodiment of the method for manufacturing a stacked capacitor according to the present invention.

First, referring to FIG. 3A, a P⁻type monocrystalline silicon substrate 11 is thermally oxidized by using a LOCOS process to form a field silicon layer 12. Then, an N⁺-type impurity diffusion region 13 is formed within the silicon substrate 11. Note that the N⁺-type impurity diffusion region 13 serves as a source region of an N-channel MOS transistor (cell transistor) (not shown). Then, an insulating layer 14 made of BPSG or silicon oxide is deposited on the entire surface. Then, a contact hole CONT1 is perforated in the insulating layer 14.

Next, referring to FIG. 3B, a phosphorus-doped polycrystalline silicon layer 15 is deposited on the entire surface by a CVD process.

Next, referring to FIG. 3C, the polycrystalline silicon layer 15 is etched back by a dry etching process, to leave a polycrystalline silicon plug 15a in the contact hole CONT1.

Next, referring to FIG. 3D, an about 50 nm thick etching stopper 16 made of silicon nitride is deposited on the entire surface by a CVD process. Then, an about 1000 nm thick silicon oxide spacer layer 17 made of silicon oxide is deposited on the etching stopper 16 by a CVD process.

Next, referring to FIG. 3E, a contact hole CONT2 is perforated in the spacer layer 17 by a photolithography and etching process. In this case, etching liquid having a large etching ratio of silicon oxide to silicon nitride is used, so that the etching stopper 16 is hardly etched.

Next, referring to FIG. 3F, the etching stopper 16 is etched by a wet or dry etching using the spacer layer 17 as a mask. As a result, the contact hole CONT2 is further deepened.

Note that the spacer layer 7 and the etching stopper 16 can be sequentially etched by one photolithography and anistropic dry etching process where the illumination strength of the etching stopper 15 is being monitored.

Next, referring to FIG. 3G, an about 50 nm thick polycrystalline silicon layer 18 is deposited on the entire surface by a CVD process.

Next, referring to FIG. 3H, a silicon oxide layer 19 is deposited on the entire surface. Then, the silicon oxide layer 19 is etched back by dry etching process. As a result, the silicon oxide layer 19 is buried in the contact hole CONT2. This buried silicon oxide layer 19 is called a core silicon oxide layer.

Next, referring to FIG. 3I, the polycrystalline silicon layer 18 is etched back. As a result, the portion of the polycrystalline silicon layer 18 on the spacer layer 17 is removed.

Next, referring to FIG. 3J, the spacer layer 17 and the silicon oxide layer 19 are etched by a wet etching process. In this case, since the etching stopper 16 made of silicon nitride is present, the insulating layer 14 is hardly etched.

Next, referring to FIG. 3K, a capacitor dielectric layer 20 is deposited on the entire surface.

Finally, referring to FIG. 3L, an about 100 nm thick capacitor upper electrode layer 21 is deposited on the entire surface, and is patterned by a photolithography and etching process.

In the first embodiment as illustrated in FIGS. 3A through 3J, since the cylindrical electrode 18 of the capacitor lower electrode layer is located on the insulating layer 14, not on the spacer layer 16, the cylindrical electrode 18 is hardly peeled from the insulating layer 16. In addition, the cylindrical electrode 18 can be substantially increased, to increase the capacity of the stacked capacitor.

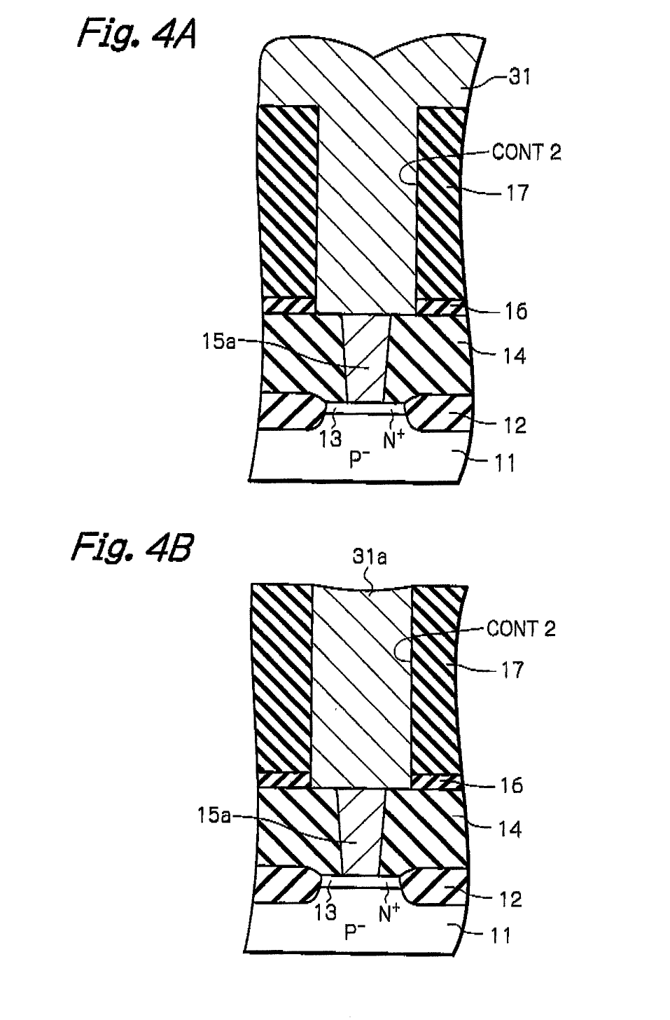

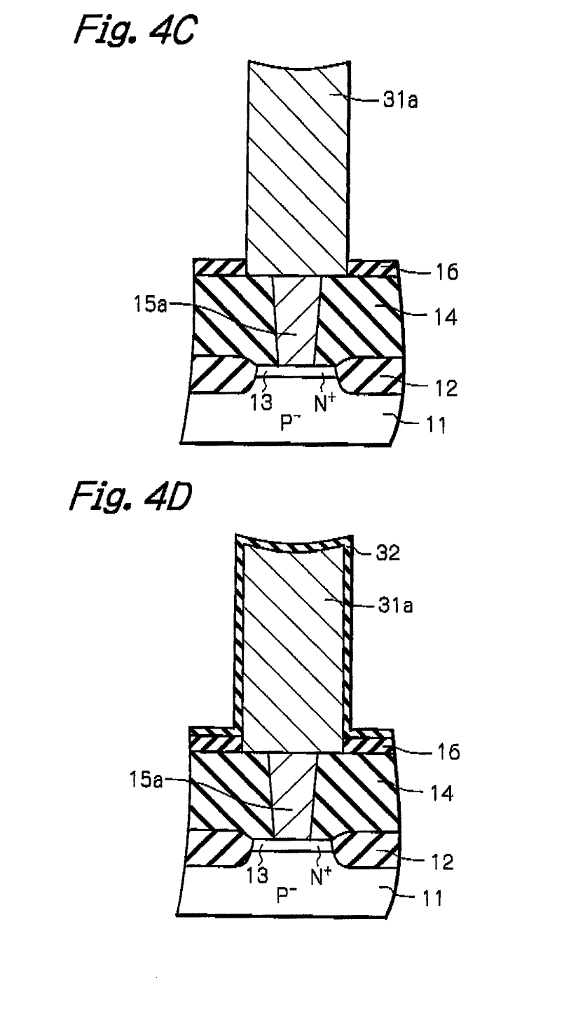

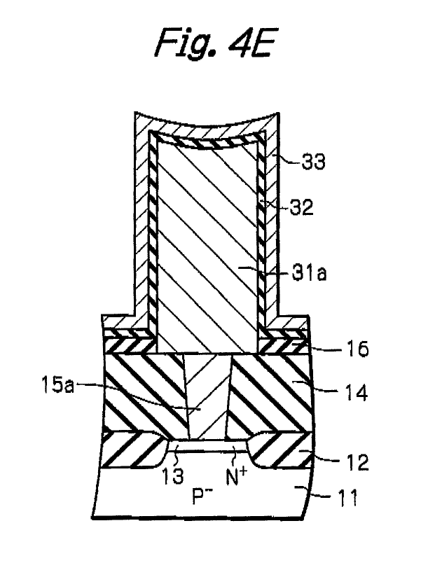

FIGS. 4A through 4E are cross-sectional views for explaining a second embodiment of the method for manufacturing a stacked capacitor according to the present invention. Note that, after the processes as illustrated in FIGS. 3A trough 3F are completed, the control proceeds to a process as illustrated in FIG. 4A.

Referring to FIG. 4A, a polycrystalline silicon layer 31 is deposited on the entire surface by a CVD process. In this case, the polycrystalline silicon layer 31 is completely buried in the contact hole CONT2.

Next, referring to FIG. 4B, the polycrystalline silicon layer 31 is etched back by a dry etching process. As a result, a polycrystalline silicon plug 31a is left in the contact hole CONT2. In this case, the polycrystalline silicon plug 31a is columnar.

Next, referring to FIG. 4C, the spacer layer 17 is etched by a wet etching process. In this case, since the etching stopper 16 made of silicon nitride is present, the insulating layer 14 is hardly etched.

Next, referring to FIG. 4D, a capacitor dielectric layer 32 is deposited on the entire surface.

Finally, referring to FIG. 4E, an about 100 nm thick capacitor upper electrode layer 33 is deposited on the entire surface, and is patterned by a photolithography and etching process.

Even in the second embodiment as illustrated in FIGS. 4A through 4E in addition to FIGS. 3A through 3F, since the columnar electrode 31a of the capacitor lower electrode layer is located on the insulating layer 14, not on the spacer layer 16, the cylindrical electrode 31a is hardly peeled from the insulating layer 16. In addition, since the columnar electrode 31a can be substantially increased, to increase the capacity of the stacked capacitor.

In the above-described embodiments, although the spacer layer 16 is made of silicon nitride, other insulating material having an etching selection ratio to the insulating layer 14, the spacer layer 17 and the core silicon oxide layer 19 can be used.

As explained hereinabove, according to the present invention, the contact characteristics of the cylindrical electrode to its underlying insulating layer can be improved without adding special process, so that the cylindrical or columnar electrode is hardly peeled form the underlying insulating layer.

1. A method for manufacturing a stacked capacitor, comprising the steps of:
forming a first insulating layer on a semiconductor substrate;
perforating a first contact hole in said first insulating layer;
burying a conductive plug in said first contact hole;
forming an etching stopper on said first insulating layer and said conductive plug;
forming a second insulating layer on said etching stopper;
perforating a second contact hole in said second insulating layer and said etching stopper;
forming an electrode layer connected to said conductive plug in said second contact hole;
etching said second insulating layer by using said etching stopper after said electrode layer is formed;
forming a capacitor dielectric layer formed on said electrode layer after said second insulating layer is etched; and
forming a capacitor upper electrode layer on said capacitor dielectric layer.

2. The method as set forth in claim 1, wherein said electrode layer forming step comprises the steps of:
forming a conductive layer on said second insulating layer and in said second contact hole;
burying a core insulating layer on said conductive layer within said second contact hole; and
etching back said conductive layer after said core insulating layer is buried.

3. The method as set forth in claim 2, wherein said electrode layer is cylindrical.

4. The method as set forth in claim 2 wherein said second insulating layer etching step etches sa core insulating layer.

5. The method as set forth in claim 1, wherein said electrode forming step buries another conductive plug in said second contact hole.

6. The method as set forth in claim 5, wherein said other conductive plug is columnar.

7. The method as set forth in claim 1, wherein said second insulating layer is made of silicon oxide, and said etching stopper is made of silicon nitride.

8. The method as set forth in claim 2, wherein said core insulating layer is made of silicon oxide.

9. A method for manufacturing a stacked capacitor, comprising the steps of:
forming a first insulating layer on a semiconductor substrate;
perforating a first contact hole in said first insulating layer;
burying a conductive plug in said first contact hole;
forming an etching stopper on said first insulating layer and said conductive plug;
forming a second insulating layer on said etching stopper;
perforating a second contact hole in said second insulating layer and said etching stopper;
forming a conductive layer on said second insulating layer and in said second contact hole;
burying a core insulating layer on said conductive layer within said second contact hole;
etching back said conductive layer after said core insulating layer is buried;
etching said second insulating layer and said core insulating layer by using said etching stopper after said conductive layer is etched back;
forming a capacitor dielectric layer formed on said etched conductive layer after said second insulating layer and said core insulating layer are etched; and
forming a capacitor upper electrode layer on said capacitor dielectric layer.

10. A method for manufacturing a stacked capacitor, comprising the steps of:
forming a first insulating layer on a semiconductor substrate;
perforating a first contact hole in said first insulating layer;
burying a first conductive plug in said first contact hole;
forming an etching stopper on said first insulating layer and said first conductive plug;
forming a second insulating layer on said etching stopper;
perforating a second contact hole in said second insulating layer and said etching stopper;
burying a second conductive plug within said second contact hole;
etching said second insulating layer by using said etching stopper after said second conductive plug is buried;
forming a capacitor dielectric layer formed on said second conductive plug after said second insulating layer is etched; and
forming a capacitor upper electrode layer on said capacitor dielectric layer.
